(19) United States
(12) Patent Application Publication
(10) Pub. No.: US 2010/0218798 A1
(43) Pub. Date: Sep. 2, 2010

(54) PIGGYBACK ADAPTER SYSTEM AND METHOD

(75) Inventors: Barry Cinnamon, Saratoga, CA (US); Wilson Leong, San Carlos, CA (US); Alex Au, Campbell, CA (US)

Correspondence Address: DLA PIPER LLP (US ), 2000 UNIVERSITY AVENUE, EAST PALO ALTO, CA, 94303-2248, US

(73) Assignee: Andalay Solar, Inc., Los Gatos, CA (US)

(21) Appl. No.: 12/395,143

(22) Filed: Feb. 27, 2009

(51) Int. Cl. H01L 31/042

(52) U.S. Cl. 136/244

(57) ABSTRACT

A piggyback adapter system and method are provided. The piggyback adapter circumvents the need for running the photovoltaic system's energy supply through a service panel (circuit breaker box).

### FIELD

A solar energy system and method are described.

### BACKGROUND

Solar power systems (that use solar panels) generate power from sunlight in the form of Direct Current (DC). One type of solar power system is a photo voltaic (PV) system, which consists of thin silicon disks that convert the sunlight into electricity. In many U.S. applications, the DC power generated by a localized PV system is converted into an Alternating Current (AC) signal at voltage levels suitable for usage in a household, and is used to supplement the power that the house obtains from a power company through the electrical grid.

Monitors placed in a house's metering device can monitor the amount of power that the solar panels generate and the amount of power that is consumed from the utility grid, offering great insight into how to manage or change the power consumption profile of a user. However, it is sometimes impossible to install monitors due in part due to the lack of space within the metering device box for sensor connectors. Additionally, the use of monitoring systems for energy use on residential homes has been stagnated because of the relatively high cost of the monitor's installation due to high electrician costs of restructuring electrical devices to accommodate the monitor's sensors.

The transmission of the energy output from the PV System to the meter also requires running the power through a circuit breaker box that contains circuits of limited power capacities. Thus, when installing a larger PV System, the circuit breaker box often must be updated to handle the larger load.

Thus, it is desirable to provide a piggyback adapter that allows easier and less expensive installation of a PV System monitor and removes the need to upgrade the existing circuit breaker when installing a localized a PV system, and it is to this end that the present invention is directed.

### BRIEF DESCRIPTION OF THE DRAWINGS

FIG. 1 illustrates a photovoltaic system;

FIG. 2 illustrates a photovoltaic system with a monitoring device;

FIG. 3 illustrates a residential power meter;

FIG. 4 illustrates an embodiment of a piggyback adapter;

FIG. 5 illustrates an embodiment of a piggyback adapter used in a photo voltaic system; and

FIG. 6 illustrates more details of an example of the piggyback adapter shown in FIGS. 4 and 5.

### DETAILED DESCRIPTION OF ONE OR MORE EMBODIMENTS

The system and method are particularly applicable to a photovoltaic system with a particular type of solar panel as described below and it is in this context that the system and method will be described. It will be appreciated, however, that the system and method in accordance with the invention has greater utility since it can be used with any type of photo voltaic system and it can be implemented in different ways than those described below while still being within the scope of the invention.

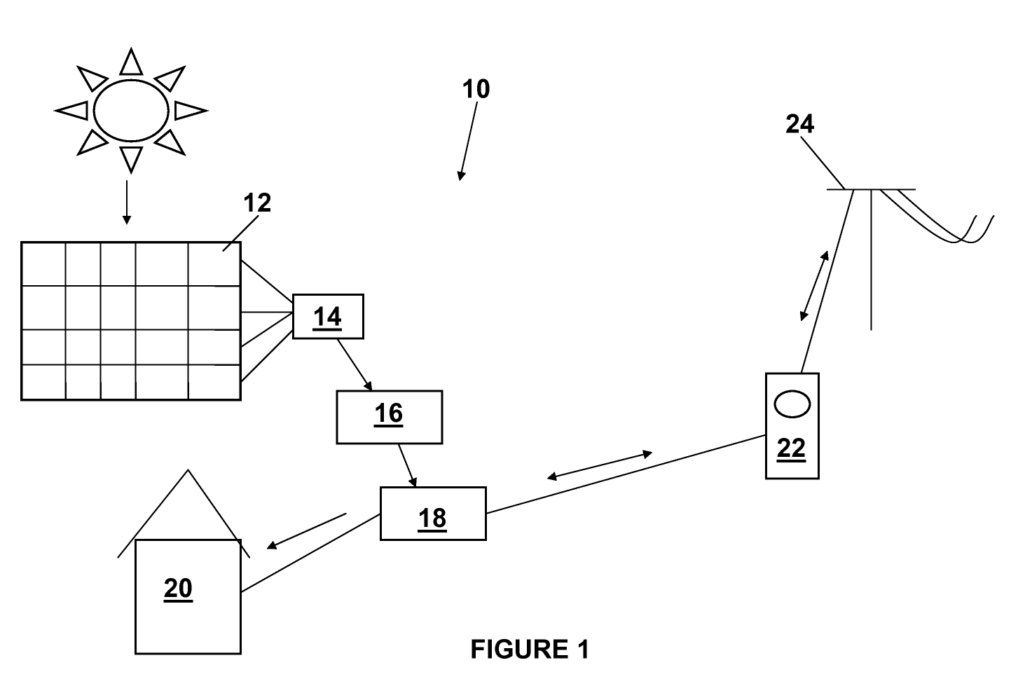

FIG. 1 illustrates a photovoltaic system 10 in which a photovoltaic system 12 (such as one or more solar panels that may rest of a roof of a house) generates energy (a DC voltage) from sunlight and the energy from the photovoltaic system are fed into a combiner box 14 that combines the power for each row of the photovoltaic system and feeds the DC voltage into a well known power inverter 16 that converts the DC voltage into an AC voltage (usable by a residence or business or in a form to be fed back into the power grid) and feeds the AC voltage to a circuit breaker panel 18. The circuit breaker panel 18 allows the AC voltage to be routed to a power user 20, such as a residence, as needed and also routed to the meter 22 so that any excess power generated by the photovoltaic system can be sent to the power grid 24 and the owner of the photovoltaic system is credited with the power that is sent to the power grid. In addition, during nighttime or when the photovoltaic system is not generating sufficient power for the power load, power can be taken from the power grid 24, through the meter 22 and circuit breaker 18 to provide power to the power user. Thus, as shown in FIG. 1, the power from the photovoltaic system is wired into the circuit breaker 18 which is a labor intensive, expensive operation. In addition, the circuit breaker box 18 must be upgraded to add circuit breakers to handle the additional power from the inverter 16. Furthermore, in many cases the circuit breaker panel does not have the capacity to handle the increased amount of power or quantity of circuit breakers, so an expensive upgrade is also required.

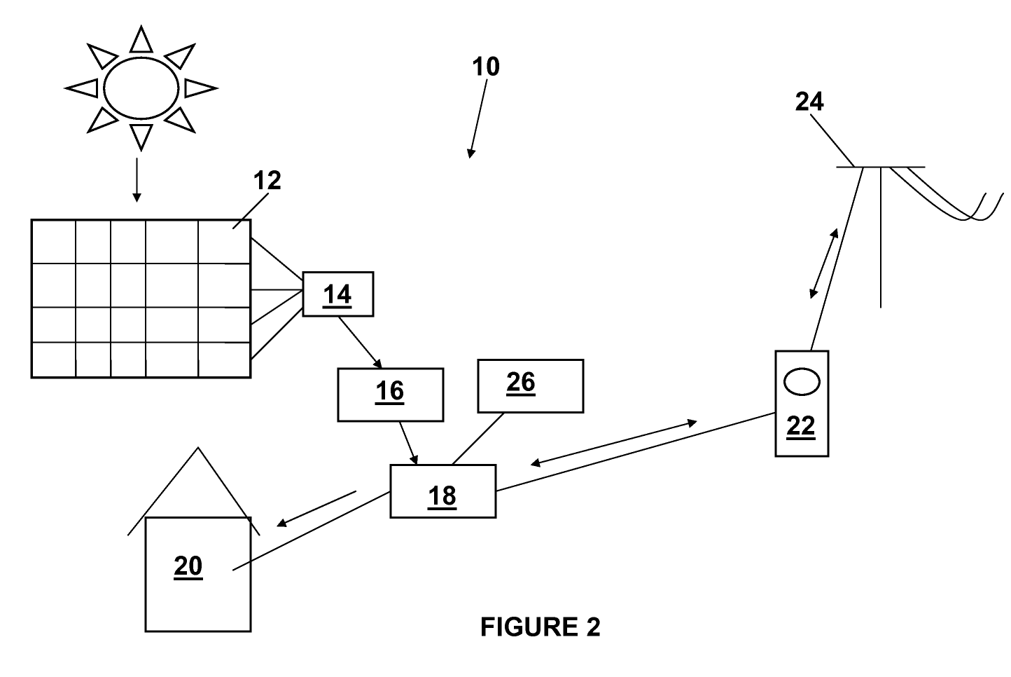

FIG. 2 illustrates a photovoltaic system with a monitoring device 26. In order to install the monitoring devices (and the electrical sensors used by the monitor), the breaker panel 18 must be further dismantled to install the electrical sensors. In addition, an additional power outlet must be provided to power the monitor.

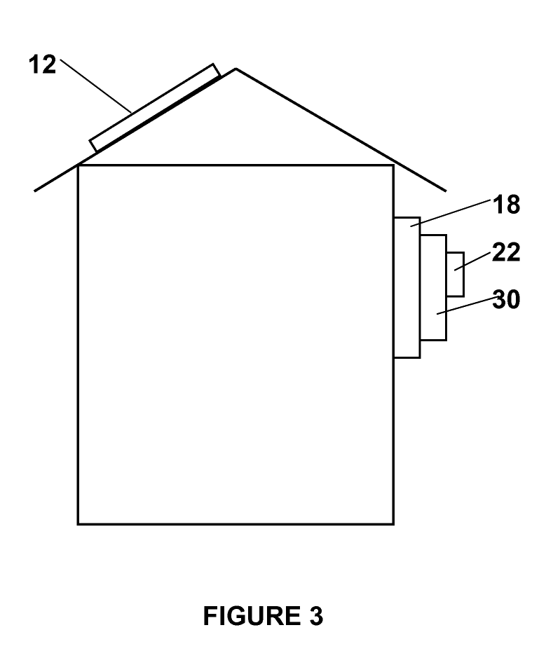

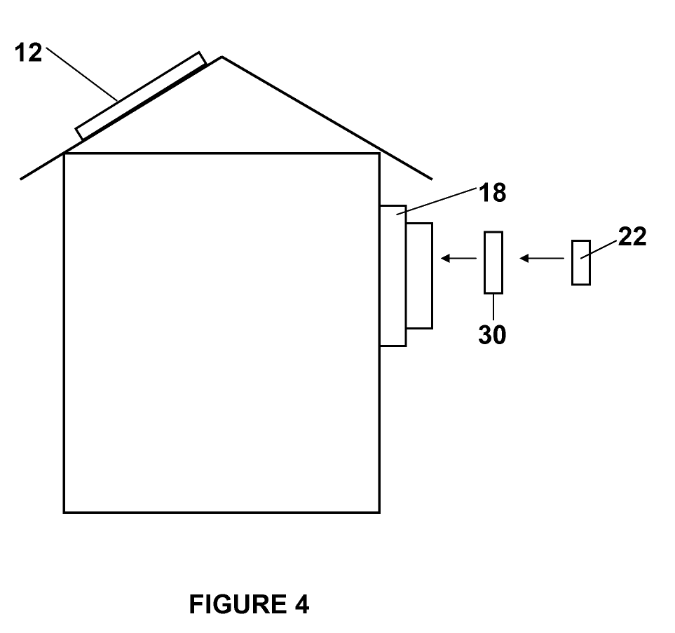

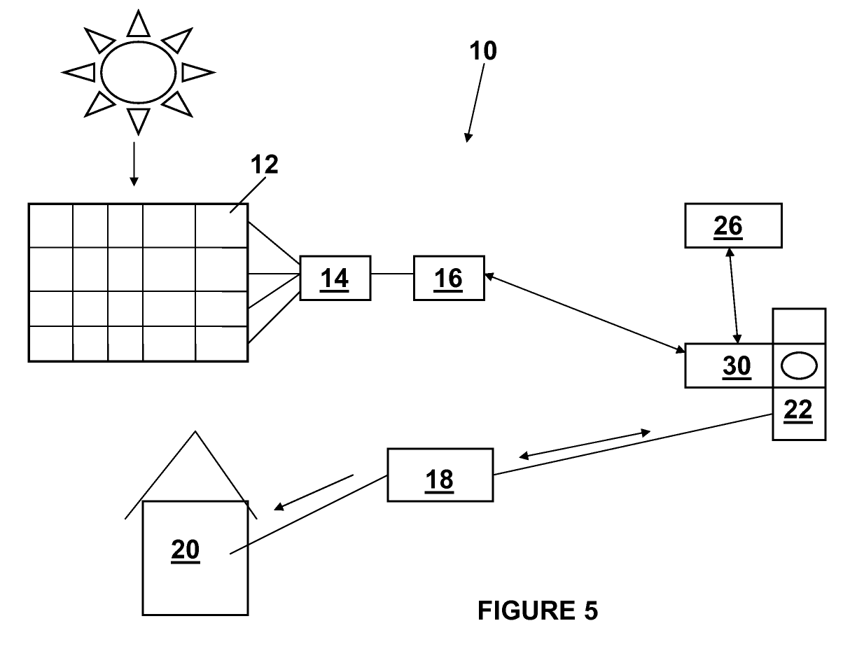

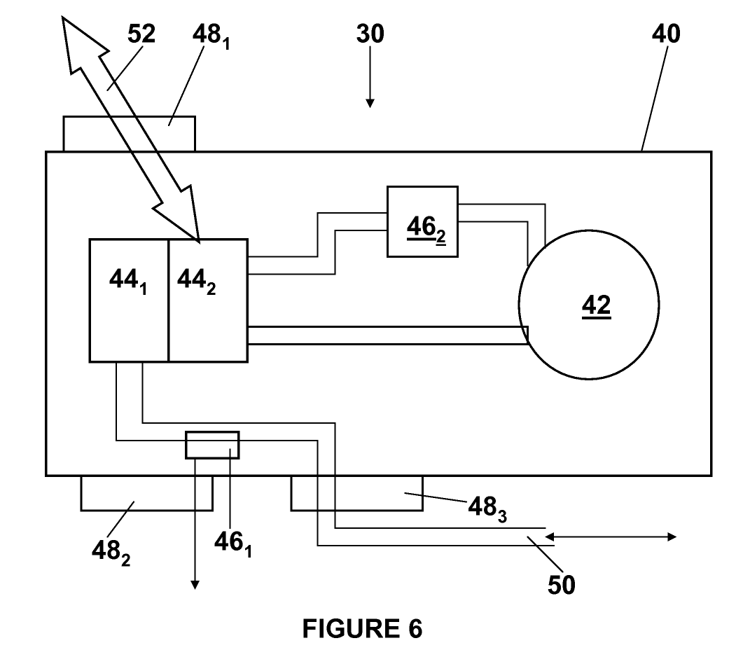

FIG. 3 illustrates a residential power meter that is mounted on the power user 20, such as a residence, that has an installed photovoltaic system 12. FIG. 4 illustrates an embodiment of a piggyback adapter 30. The residence may include the circuit breaker panel and the power meter 22 and may further include the piggyback adapter 30. FIG. 5 illustrates an embodiment of a piggyback adapter 30 used for a photovoltaic system in which the power from the inverter 16 is fed directly into the piggyback adapter 30 as shown. The piggyback adapter contains circuit breakers 18 and connects directly to the monitor device 26. The piggyback adapter (described in more detail below with reference to FIG. 6) circumvents the need for running the energy of the photovoltaic system 12 through a service panel (the circuit breaker box 18) as it contains its own circuit breakers and connects the output of the inverter 16 directly to the meter box, significantly reducing costs and increasing benefits.

In one embodiment, the piggyback adapter 30 may be placed directly behind the meter 22 (as shown in FIGS. 4 and 5). The location of the piggyback adapter directly behind the meter 22 means that the dismantling and upgrading of the circuit breaker box is unnecessary since the solar panel power from the inverter runs through the adapter's circuit breakers then connects directly through the meter box. In addition, the monitor sensors (as shown in more detail in FIG. 6) are installed in the piggyback box so further dismantling of the breaker box is unnecessary. In addition, providing a power outlet for the monitor box is not required since the monitor will be connected through the piggyback box which significantly reduces the material and labor for installing the monitor. The piggyback adapter also provides a lockable utility disconnect capability (lever and lock down of energy generated by the PV system 12). Furthermore, since the current of the PV system 12 does not pass through the original circuit breaker 18, there is no longer the need to upgrade the breaker panel 18 if a user wants to install a larger PV system. The piggyback adapter also facilitates an easier method of connecting the power inverter 16 into the household electrical system since the connection directly to the meter base eliminates labor and material intensive activities that are normally encountered when connecting the power inverter through the circuit breaker panel.

FIG. 6 illustrates more details of an example of the piggyback adapter 30 shown in FIGS. 4 and 5. The piggyback adapter connects the output of the inverter and provides power to the monitor and an electric vehicle plug-in, and provides pick up points for the monitor's power sensors, with circuit breaker protection. The piggyback adapter 30 may be an enclosure 40 that houses various components including a piggyback mechanism 42, one or more circuit breakers 44, such as circuit breakers 44₁ and 44₂ as shown in the example shown in FIG. 6, one or more power sensors 46, such as sensors 46₁ and 46₂ as shown in the example shown in FIG. 6, and one or more ports 48, such as the 48₁, 48₂ and 48₃ as shown in the example shown in FIG. 6. One of the ports may be used for a connection for charging an electric vehicle.

The piggy back mechanism 42 is the device which enables the unit to be physically and electrically inserted between existing power meter and the power meter base, allowing for easy electrical connection from the PV system to the household electrical lines and easy installation of a monitoring system and/or electric vehicle plug-in. The enclosure of the piggyback adapter is a circular, lipped shape that joins directly to the meters face, with a plurality of conductors on each side that allow electricity to flow directly to the meter and receive electricity from the electric grid. The adapter also has a plurality of transducive devices that can monitor the amount of electrical current flowing in the aforementioned plurality of conductors.

The housing of the piggyback device has a plurality of port openings, which includes but is not limited to: one for the wires transmitting power from the inverter/PV System source to the piggyback adapter's circuit breakers; one for the wires transmitting power from either the inverter/PV System source or the utility electric source to an electric vehicle plug-in; and one for the wires transmitting power from either the inverter/PV System source or the utility electric source to a remote monitoring system plug. Thus, power can either flow from the utility electric source through the piggyback adapter's circuit breaker then the electric vehicle port or the remote monitoring port, or the power from the PV System source will flow to the breaker then directly to the out-ports to the electric vehicle or remote monitoring system. The PV System source will always supply the first source of power, with the utility power supply acting as its backup. The one or more circuit breakers 44 provide electrical over-current protection for the power inverter feed 50, the electric vehicle load, and the monitoring system load 52.

The power sensor pickup points 46 may be conductors between the piggyback mechanism 42 and the circuit breakers 44 that are of proper shape to facilitate installation of sensors to detect the amount of current that is flowing in that circuit. Sensors can be, but not limited to, devices commonly referred to as current transducers. The output from the sensors 46 may be fed to the monitor device. For example, each sensor may be a well known current transducer which is a commercially available product made by many different manufacturers.

While the foregoing has been with reference to a particular embodiment of the invention, it will be appreciated by those skilled in the art that changes in this embodiment may be made without departing from the principles and spirit of the invention, the scope of which is defined by the appended claims.

1. A piggyback adapter for a photovoltaic system, comprising:
an enclosure that has one or more ports that receive at least an inverter path, a monitor power path, an electric grid path and an electric vehicle charging path;
a piggyback mechanism that fits between a power meter and a power meter base;
one or more circuit breakers that prevent over-current along the monitor power path and along the inverter path; and
one or more sensors that measure the current along the monitor power path and along the inverter path.

2. The adapter of claim 1, wherein the inverter path further comprises one or more conductors that connect the adapter to an inverter.

3. The adapter of claim 1, wherein the monitor path further comprises one or more conductors that connect the adapter to a monitor device.

4. The adapter of claim 1 further comprising a lockable utility disconnect.

5. The adapter of claim 1, wherein the enclosure joins to a face of the power meter.

6. An electrical system, comprising:
a photo-voltaic system that generates a direct current voltage;
an inverter that converts the direct current voltage into an alternative current voltage;
a monitor device that monitors the electrical system;
a piggyback adapter having an enclosure that has one or more ports that receive at least an inverter path and a monitor power path and an electric vehicle charging path, a piggyback mechanism that fits between a power meter and a power meter base, one or more circuit breakers that prevent over-current along the monitor power path and along the inverter path; and one or more sensors that measure the current along the monitor power path and along the inverter path.

7. The system of claim 6, wherein the photo-voltaic system further comprises one or more solar panels.

8. The system of claim 7 further comprising a combiner that combines a voltage output from the one or more solar panels and inputs the combined voltage output into the inverter.
